(19) United States
(12) Patent Application Publication
(10) Pub. No.: US 2026/0334305 A1
(43) Pub. Date: Oct. 22, 2026

(54) SEMICONDUCTOR PACKAGE AND METHOD FOR FORMING THE SAME

(71) Applicant: TAIWAN SEMICONDUCTOR MANUFACTURING COMPANY LTD., HSINCHU (TW)

(72) Inventors: MING-HAN LIAO, HSINCHU (TW); CHEWN-PU JOU, HSINCHU CITY (TW); CHIH-HAO WANG, HSINCHU COUNTY (TW); MIN CAO, HSINCHU (TW)

(21) Appl. No.: 19/182,771

(22) Filed: Apr. 18, 2025

(51) Int. Cl. H01L 25/16; G02B 6/42; G02B 6/43; H01L 21/48; H01L 23/00; H01L 23/48; H01L 23/538; H10B 80/00; H10D 80/30

(52) U.S. Cl. CPC H10W 90/00; G02B 6/4245; G02B 6/43; H10B 80/00; H10D 80/30; H10W 20/20; H10W 70/095; H10W 70/611; H10W 70/65; H10W 90/401; H10W 80/312; H10W 80/327; H10W 90/722; H10W 90/724; H10W 90/794

(57) ABSTRACT

A semiconductor package and a method for forming the same are provided. The semiconductor package includes a substrate, an interconnect structure, a first routing structure, and a first photonic integrated circuit (PIC). The substrate includes a device region at a front surface of the substrate, and the substrate includes a logic device. The interconnect structure is over the device region. The interconnect structure includes interconnect layers, each of the interconnect layers includes metal lines disposed in a dielectric layer, a first metal line in a first interconnect layer of the interconnect layers is spaced apart from a second metal line in a second interconnect layer of the interconnect layers by the dielectric layer. The first routing structure is disposed over a back surface of the substrate and is configured to communicate the logic device with an external component. The first PIC is integrated into the first routing structure.

### BACKGROUND

The current Co-Packaged-Optics (CPO) technology places silicon photonic devices on a broad and/or an interposer for data transmission. The amount of connection input/output (I/O) terminals are limited due to the amount of the I/O terminals on the board and/or the interposer. In addition, the distance between the silicon photonic devices and logic devices on the broad and/or the interposer is relatively long. Therefore, for high speed and high bandwidth computing performance in AI related applications, it is a challenge to provide new device scheme and structures with silicon photonic devices to solve the above issues.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1A is a cross-sectional view of a semiconductor package according to one or more embodiments of the present disclosure.

FIG. 1B is a cross-sectional view of a semiconductor package according to one or more embodiments of the present disclosure.

FIG. 1C is a perspective view of a portion of a semiconductor package according to one or more embodiments of the present disclosure.

FIGS. 2A to 2E are cross-sections illustrating a method for forming a semiconductor package according to one or more embodiments of the present disclosure.

FIG. 3A is a cross-sectional view of a semiconductor package according to one or more embodiments of the present disclosure.

FIG. 3B is a cross-sectional view of a semiconductor package according to one or more embodiments of the present disclosure.

FIG. 3C is a top view of a portion of a semiconductor package according to one or more embodiments of the present disclosure.

FIG. 3D is a perspective view of a portion of a semiconductor package according to one or more embodiments of the present disclosure.

FIG. 3E is a perspective view of a portion of a semiconductor package according to one or more embodiments of the present disclosure.

FIGS. 4A to 4G are cross-sections illustrating a method for forming a semiconductor package according to one or more embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” or “about” generally mean within a value or range that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

Embodiments of the present disclosure discuss a semiconductor package including a photonic integrated circuit (PIC) integrated into a routing structure over a back side of a logic device. Since the PIC is bonded to the logic device without a board or an interposer interposed therebetween, the amount of the connection I/O terminals are increased significantly. Accordingly, the signal transmission speed is increased significantly, which is advantageous to high speed and high bandwidth is computing performance in AI related applications. Therefore, the system performance of the semiconductor package can be improved significantly.

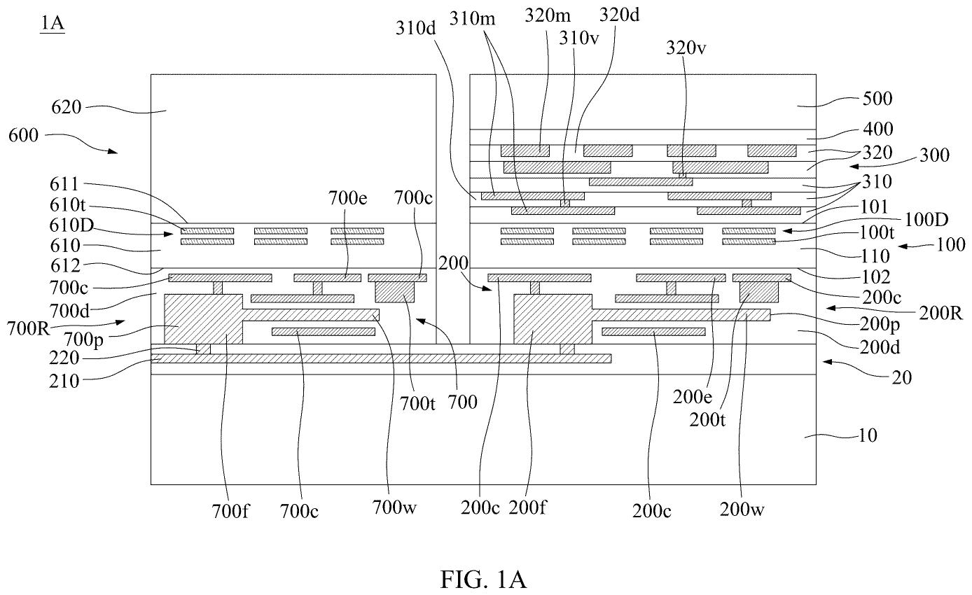

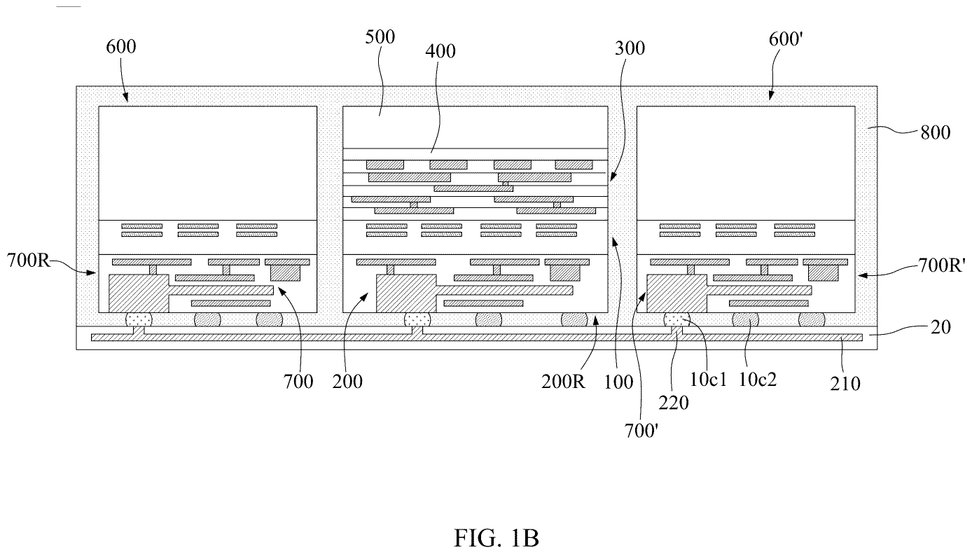

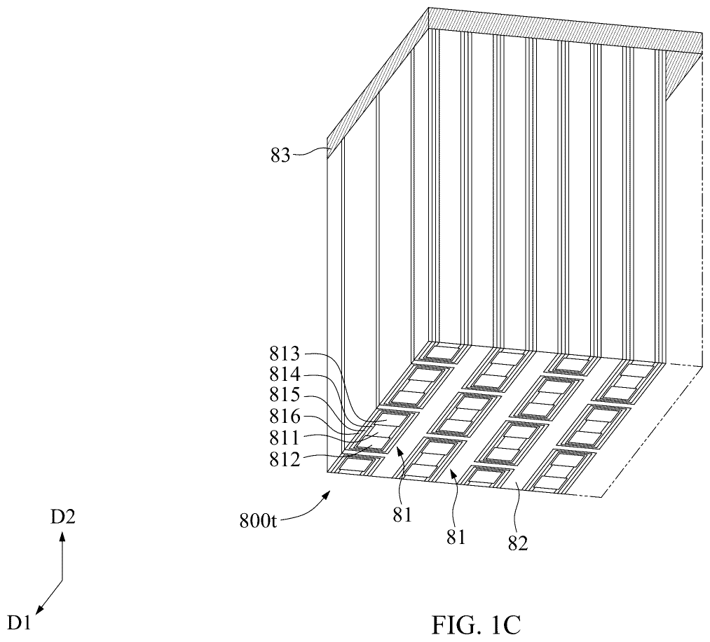

FIG. 1A is a cross-sectional view of a semiconductor package 1A according to one or more embodiments of the present disclosure. The semiconductor package 1A may include a carrier 10, an optical interposer 20, a substrate 100, silicon photonic (SiPh) structures 200 and 700, interconnect structures 200R, 300, and 700R, a bonding layer 400, a carrier wafer 500, and a memory device 600. The semiconductor package 1A may be referred to as a semiconductor device, a partial structure of a semiconductor device, an optoelectronic device, or a partial structure of an optoelectronic device.

The carrier 10 may be or include a package component. In some embodiments, the carrier 10 is or includes a package substrate, a printed circuit board (PCB), an interposer, a package, or the like. The carrier 10 may have a top surface for supporting at least the optical interposer 20, the substrate 100, and the memory device 600.

The optical interposer 20 may be disposed over the carrier 10. In some embodiments, the optical interposer 20 is disposed below the substrate 100 and optically coupled to the substrate 100 through the SiPh structure 200. In some embodiments, the optical interposer 20 includes one or more optical coupling elements, such as at least an optical waveguide 210 and optical terminals 220. The optical waveguide 210 and the optical terminals 220 collectively may be referred to as an optical coupling structure configured to communicate with the device region 100D in the substrate 100 through the SiPh structure 200.

The substrate 100 may be disposed over the carrier 10. The substrate 100 may have a front surface 101 (or a top surface) and a back surface 102 (or a bottom surface) opposite to the front surface 101. In some embodiments, the substrate 100 includes a semiconductor layer 110 (e.g., a semiconductor substrate or a silicon-based substrate layer) and a device region 100D at least partially in the semiconductor layer 110. The semiconductor layer 110 may be referred to as a core Si. In some embodiments, the device region 100D includes a plurality of device layers 100t. One or more of the device layers 100t may include a plurality of transistors (e.g., nanosheet GAA transistors, forksheet transistors, CFETs, or the like). In some embodiments, the device region 100D is at or adjacent to the front surface 101 of the substrate 100 (or the semiconductor layer 110). The substrate 100 may include at least a logic circuit, such as a processer including a CPU, a GPU, an xPU, an FPGA, an ASIC, or a combination thereof. The substrate 100 may be referred to as a logic device. The device region 100D of the substrate 100 may include one or more logic dies (or logic circuits) for high-speed logic computing purposes. The logic die may include nanosheet GAA transistors, forksheet transistors, CFETs, or the like.

The interconnect structure 200R may be disposed or formed below the substrate 100. In some embodiments, the interconnect structure 200R is formed on or bonded to the back surface 102 (or the bottom surface) of the substrate 100 (or the semiconductor layer 110). In some embodiments, the interconnect structure 200R includes a plurality of interconnect layers 200c and a dielectric structure 200d including a plurality of dielectric layers. Each of the interconnect layers 200c may include metal lines disposed in one of the dielectric layers, and the metal lines are spaced apart from one another by at least one of the dielectric layers. In some embodiments, the interconnect structure 200R is configured to communicate the substrate 100 (or the logic device) with an external component (e.g., the memory device 600). In some embodiments, electrical signals of the transistors and/or circuits in the device region 100D are transmitted to the external component through the interconnect layers 200c of the interconnect structure 200R. The interconnect structure 200R may be referred to as a routing structure.

The SiPh structure 200 may be formed or disposed below the substrate 100. In some embodiments, the SiPh structure 200 is formed on, connected to, or bonded to the back surface 102 (or the bottom surface) of the substrate 100 (or the semiconductor layer 110) and electrically connected to the device region 100D of the substrate 100. In some embodiments, the substrate 100 is optically coupled to the optical interposer 20 through the SiPh structure 200. In some embodiments, the SiPh structure 200 is vertically stacked between the optical interposer 20 and the substrate 100. In some embodiments, the SiPh structure 200 includes an electrical integrated circuits (EIC) and a photonic integrated circuits (PIC) electrically connected to and integrated with the EIC. In some embodiments, the PIC and the EIC are integrated into the interconnect structure 200R (or the routing structure). The term “integrated into” used hereinafter indicates that elements and/or features of the PIC and the EIC are formed with the interconnect structure 200R. For example, the elements and/or the features of the PIC and the EIC may be formed within the dielectric structure 200d of the interconnect structure 200R. In some embodiments, the dielectric structure 200d covers the EIC and the PIC and contacts the back surface 102 of the substrate 100. In some embodiments, the logic die (or the logic circuit), the EIC, and the PIC share the semiconductor layer 110 of the substrate 100. In some embodiments, the PIC is optically coupled to the optical interposer 20. The PIC may be configured to process, receive and/or transmit one or more electrical signals converted to/from one or more optical signals. The PIC may be configured to generate one or more optical signals based on an input from the EIC, for example, in the visible spectrum or near infrared 850 nm-1650 nm. The EIC may include a controller, a driver, an amplifier, or a combination thereof integrated into the interconnect structure 200R, and the PIC may include a photodetector, a modulator, a laser, a waveguide, an edge coupler, a grating coupler, or a combination thereof integrated into the interconnect structure 200R.

In some embodiments, the SiPh structure 200 includes electrical portions 200e configured for electrical coupling and optical portions 200p configured for optical coupling, and the dielectric structure 200d covers the electrical portions 200e and the optical portions 200p. The optical portions 200p may be referred to as optical coupling layers, optical channels, or an optical coupling structure. The dielectric structure 200d may include multiple dielectric layers. The dielectric structure 200d may include a cladding material for the optical portions 200p (or the optical channels). In some embodiments, the EIC is formed of at least some of the electrical portions 200e, and the PIC is formed of at least some of the optical portions 200p and integrated with the electrical portions 200e of the EIC. The EIC may be or include circuit layers formed of at least some of the electrical portions 200e, and the PIC may be or include photonic devices formed of at least some of the optical portions 200p. In some embodiments, the circuit layers of the EIC are disposed or formed on the back surface 102 of the substrate 100 and electrically connected to the device region 100D, and the photonic device of the PIC are disposed or formed between the circuit layers. In some embodiments, the EIC (e.g. the electrical portions 200e of the EIC) includes at least an element 200t, which may be also referred to as an electronic element, an electronic device, or an electronic component. In some embodiments, the element 200t is or includes a controller, a driver, and/or an amplifier electrically connected to the device region 100D. In some embodiments, the EIC (e.g. the electrical portions 200e of the EIC) further includes interconnect layers. The electrical portions 200e may include one or more interconnect layers formed integrally with one or more interconnect layers 200c, and the interconnect layers of the electrical portions 200e may be at least partially covered by the dielectric structure 200d. In some embodiments, the PIC (e.g. the optical portions 200p of the PIC) includes elements 200w and 200f, which may be also referred to as optical elements, photonic devices, or photonic components. In some embodiments, the element 200w is a waveguide optically coupled to the element 200f and/or the optical terminal 220 of the optical interposer 20. In some embodiments, the element 200f includes a photodetector and/or a modulator that is electrically connected to the EIC through the interconnect layer 200c and optically coupled to the waveguide. In some embodiments, the element 200f includes a laser and/or a coupler that is optically coupled to the waveguide, the photodetector, and/or the modulator. In some embodiments, the EIC includes the electrical portions 200e between the substrate 100 and the element 200f. In some embodiments, at least one of the interconnect layers 200c of the interconnect structure 200R is between the optical interposer 20 and the element 200f.

The interconnect structure 300 may be disposed or formed over the device region 100D of the substrate 100. In some embodiments, the interconnect structure 300 includes a plurality of interconnect layers 310 and 320. In some embodiments, each of the interconnect layers includes metal lines disposed in a dielectric layer, and the metal lines are spaced apart from one another by the dielectric layer. For example, the interconnect layer 310 may include a dielectric layer 310d and metal lines 310m and 310v disposed in and spaced apart from one other by the dielectric layer 310d, and the interconnect layer 320 may include a dielectric layer 320d and metal lines 320m and 320v disposed in and spaced apart from one other by the dielectric layer 320d. In some embodiments, the interconnect structure 300 is configured to communicate logic dies (e.g., the logic dies in device region 100D) at the front surface 101 of the substrate 100 (or the logic device). In some embodiments, the interconnect structure 300 is configured to electrically communicate the transistors and/or circuits in the device region 100D. In some embodiments, electrical signals of the transistors and/or circuits in the device region 100D are transmitted to one another through the interconnect layers of the interconnect structure 300. The interconnect structure 300 may be referred to as a routing structure.

In some embodiments, two metal lines of the interconnect layers extend along different directions. For example, the metal line 310m and the metal line 310v may extend along different directions. In some embodiments, a first metal line in a first interconnect layer of the interconnect layers is spaced apart from a second metal line in a second interconnect layer of the interconnect layers by a dielectric layer, and the first metal line is electrically coupled to the second metal line by a via disposed in the dielectric layer. For example, the metal lines 310m in adjacent interconnect layers 310 are spaced apart from each other by the dielectric layer 310d and are electrically coupled to each other by a via (e.g., the metal line 310v). In some embodiments, a thickness of a respective dielectric layer in a bottommost one of the interconnect layers is less than a thickness of a respective dielectric layer in at least one of the interconnect layers above the bottommost one of the interconnect layers. For example, a thickness of the dielectric layer 310d in the bottommost interconnect layer 310 is less than a thickness of the dielectric layer 320d in the interconnect layer 320 above the bottommost interconnect layer 310.

The interconnect structure 200R that integrates with the SiPh structure 200 may be or include a back side routing structure between the optical interposer 20 and the substrate 100, and the interconnect structure 300 may be or include a front side routing structure over and electrically connected to the logic circuit of the substrate 100. In some embodiments, the front side routing structure is configured for communication between logic dies or logic circuits (e.g., the transistors in the device region 100D), and the back side routing structure is configured to connect to external components. In some embodiments, signal communication between the logic circuit and external components is achieved by optical communication through the optical interposer 20.

In some embodiments, the back side routing structure includes or integrates with an EIC electrically connecting the logic circuit to the PIC. In some embodiments, the PIC is configured to convert an optical signal to an electrical signal and then transmit the electrical signal to the EIC. In some embodiments, the PIC is configured to receive an electrical signal from the EIC and convert the electrical signal to an optical signal. In some embodiments, the EIC and the PIC are integrated into the back side routing structure that is configured to connect to external components. In some embodiments, a plurality of silicon photonic modules each including a set of EIC/PIC may be integrated into the back side routing structure on the back side of the core Si (e.g., the semiconductor layer 110 of the substrate 100). In some embodiments, the technology node for the EIC and the PIC is greater than the technology node for the logic circuit. For example, the technology node for the EIC may be about N7 (about 7 nm), the technology node for the PIC may be about N65 (about 6.5 nm), and the technology node for the logic circuit may be about N2 or N3 (about 2 nm or 3 nm).

In some embodiments, the back side routing structure on the back side of the core Si includes electrically conductive structures for providing electrical signals from the logic circuits to the EIC and optionally for transmitting power. In some embodiments, the back side routing structure on the back side of the core Si further includes optical channels for transmitting optical signals within the PIC and from the PIC to an optical interposer external to the PIC.

In some embodiments, the front side routing structure is configured to electrically connect the components (e.g., transistors) within the logic circuit (or the logic device). The front side routing structure may include a plurality of metal layers or metal routings (e.g., the interconnect layers 310 and 320).

The bonding layer 400 may connect the carrier wafer 500 to the interconnect structure 300. In some embodiments, the bonding layer 400 is or includes an oxide layer, e.g., a silicon oxide layer. In some embodiments, the carrier wafer 500 is or includes a semiconductor substrate, e.g., a silicon substrate. The carrier wafer 500 may serve as a buffer carrier during manufacturing processes and as a protective layer for the interconnect structure 300.

The memory device 600 may be disposed over and optically coupled to the optical interposer 20. In some embodiments, the memory device 600 includes a logic die 610 and a memory component 620. The logic die 610 may have a front surface 611 (or a top surface) and a back surface 612 (or a bottom surface) opposite to the front surface 611. In some embodiments, the logic die 610 includes a semiconductor layer (e.g., a semiconductor substrate or a silicon-based substrate layer) and a device region 610D at least partially in the semiconductor layer. In some embodiments, the device region 610D includes a plurality of device layers 610t. One or more of the device layers 610t may include a plurality of transistors (e.g., nanosheet GAA transistors, forksheet transistors, CFETs, or the like). In some embodiments, the device region 610D is at or adjacent to the front surface 611 (or the top surface) of the logic die 610 (or the semiconductor layer of the logic die 610). The logic die 610 may be or include a CPU, a GPU, a MCU, an AP, or the like including at least a logic circuit. The memory component 620 may be on the front surface 611 and include a memory stack. In some embodiments, the memory device 600 is configured to communicate with the device region 100D of the substrate 100 through an optical coupling between the SiPh structure 200 and the SiPh structure 700.

The interconnect structure 700R may be disposed or formed below the memory device 600. In some embodiments, the interconnect structure 700R is formed on or bonded to the back surface 612 (or the bottom surface) of the memory device 600 (or the semiconductor layer of the logic die 610). In some embodiments, the interconnect structure 700R includes a plurality of interconnect layers 700c and a dielectric structure 700d including a plurality of dielectric layers. Each of the interconnect layers 700c may include metal lines disposed in one of the dielectric layers, and the metal lines are spaced apart from one another by at least one of the dielectric layers. In some embodiments, the interconnect structure 700R is configured to communicate the logic die 610 with an external component (e.g., the device region 100D). In some embodiments, electrical signals of the transistors and/or circuits in the logic die 610 are transmitted to the external component through the interconnect layers 700c of the interconnect structure 700R. The interconnect structure 700R may be referred to as a routing structure.

The SiPh structure 700 may be formed or disposed below the memory device 600. In some embodiments, the SiPh structure 700 is formed on, connected to, or bonded to the back surface 612 (or a bottom surface) of the memory device 600 (or the semiconductor layer of the logic die 610) and electrically connected to the device region 610D of the logic die 610. In some embodiments, the memory device 600 is optically coupled to the optical interposer 20 through the SiPh structure 700. In some embodiments, the SiPh structure 700 is vertically stacked between the optical interposer 20 and the logic die 610. In some embodiments, the SiPh structure 700 includes an EIC and a PIC electrically connected to and integrated with the EIC. In some embodiments, the PIC and the EIC are integrated into the interconnect structure 700R (or the routing structure). The term “integrated into” used hereinafter indicates that elements and/or features of the PIC and the EIC are formed with the interconnect structure 700R. For example, the elements and/or the features of the PIC and the EIC may be formed within the dielectric structure 700d of the interconnect structure 700R. In some embodiments, the dielectric structure 700d covers the EIC and the PIC and contacts the back surface 612 of the logic die 610. In some embodiments, the logic circuit in the device region 610D, the EIC, and the PIC share the semiconductor layer of the logic die 610. In some embodiments, the PIC is optically coupled to the optical interposer 20. The PIC may be configured to process, receive and/or transmit one or more electrical signals converted to/from one or more optical signals. The PIC may be configured to generate one or more optical signals based on an input from the EIC, for example, in the visible spectrum or near infrared 850 nm-1650 nm. The EIC may include a controller, a driver, an amplifier, or a combination thereof integrated into the interconnect structure 700R, and the PIC may include a photodetector, a modulator, a laser, a waveguide, an edge coupler, a grating coupler, or a combination thereof integrated into the interconnect structure 700R.

In some embodiments, the SiPh structure 700 includes electrical portions 700e configured for electrical coupling and optical portions 700p configured for optical coupling, and the dielectric structure 700d covers the electrical portions 700e and the optical portions 700p. The optical portions 700p may be referred to as optical coupling layers, optical channels, or an optical coupling structure. The dielectric structure 700d may include multiple dielectric layers. The dielectric structure 700d may include a cladding material for the optical portions 700p (or the optical channels). In some embodiments, the EIC may be or include circuit layers formed of at least some of electrical portions 700e, and the PIC may be or include photonic devices formed of at least some of optical portions 700p and integrated with the electrical portions 700e of the EIC. In some embodiments, the circuit layers of the EIC are disposed or formed on the back surface 612 of the logic die 610 and electrically connected to the device region 610D, and the photonic device of the PIC are disposed or formed between the circuit layers. In some embodiments, the EIC (e.g. the electrical portions 700e of the EIC) includes at least an element 700t, which may be also referred to as an electronic element, an electronic device, or an electronic component. In some embodiments, the element 700t is or includes a controller, a driver, and/or an amplifier electrically connected to the logic die 610. In some embodiments, the EIC (e.g. the electrical portions 700e of the EIC) further includes interconnect layers. The electrical portions 700e may include one or more interconnect layers formed integrally with one or more interconnect layers 700c, and the interconnect layers of the electrical portions 700e may be at least partially covered by the dielectric structure 700d. In some embodiments, the PIC (e.g. the optical portions 700p of the PIC) includes elements 700w and 700f, which may be also referred to as optical elements, photonic devices, or photonic components. In some embodiments, the element 700w is a waveguide optically coupled to the element 700f. In some embodiments, the element 700f includes a photodetector, a modulator, or a combination thereof that is electrically connected to the interconnect layer 700c and optically coupled to the optical terminal 220 of the optical interposer 20. In some embodiments, the element 700f includes a laser that is optically coupled to the waveguide and the modulator. In some embodiments, the EIC includes the electrical portions 700e between the logic die 610 and the element 700f. In some embodiments, at least one of the interconnect layers 700c of the interconnect structure 700R is between the optical interposer 20 and the element 700f.

The current Co-Packaged-Optics (CPO) technology places silicon photonic devices on a broad (e.g., a PCB) and/or an interposer for signal transmission; however, the amount of connection input/output (I/O) terminals are limited by the amount of the I/O terminals on the board and/or the interposer. That is, the connection I/O density between the silicon photonic devices and logic devices is limited to the I/O density provided by the board and/or the interposer. Therefore, the I/O density is relatively low. In addition, the distance between the silicon photonic devices and the logic devices are relatively long, and the signal transmission between the silicon photonic devices and the logic devices through the board and/or the interposer is relatively slow due to the relatively long distance.

Simulation results show that the I/O density of the semiconductor package 1A is about 1E9 mm², the I/O density of a semiconductor package including a silicon photonic device hybrid-bonded to a board and a logic device hybrid-bonded to the board is about 1E7 mm², and the I/O density of a CPO package is about 1E4 mm². The simulation was performed using FDTD (Finite-Difference Time-Domain) tool.

According to some embodiments of the present disclosure, the EIC and the PIC of the SiPh structure 200 are integrated to the back side of the logic device (e.g., the back surface 102 of the substrate 100 including the device region 100D at the front surface 101). Since the EIC and the PIC are bonded to the logic device without a board (e.g., the carrier 10) or an interposer interposed therebetween, the amount of the connection I/O terminals are increased significantly, as shown from the simulation results above. Accordingly, the signal transmission speed is increased significantly, which is advantageous to high speed and high bandwidth is computing performance in AI related applications. Therefore, the system performance of the semiconductor package 1A can be improved significantly.

In addition, according to some embodiments of the present disclosure, the logic circuit (e.g., the device region 100D) and the EIC and the PIC of the SiPh structure 200 share the semiconductor layer 110 of the substrate 100 (e.g., the core Si). That is, the logic circuit and the silicon photonic structure of the semiconductor package 1A may be formed on the same substrate during the manufacturing process rather than being formed on separate substrates and then assembled together with two substrates remained in the semiconductor package or semiconductor device. Accordingly, the distance between the PIC and the logic circuit is relatively small, such that the transmission path is reduced, which is advantageous to increasing the logic computing speed. Moreover, the semiconductor layer may be thinned while it is interposed between the logic circuit and the PIC, such that the distance between the PIC and the logic circuit may be further shortened.

Moreover, according to some embodiments of the present disclosure, the EIC and the PIC are integrated into the back side routing structure that is configured to connect the logic circuit to external components. Therefore, extra space for disposing or forming the silicon photonic device is omitted, and thus the volume (or the size) of the semiconductor package 1A is reduced.

FIG. 1B is a cross-sectional view of a semiconductor package 1B according to one or more embodiments of the present disclosure. The semiconductor package 1B illustrated in FIG. 1B is similar to the semiconductor package 1A illustrated in FIG. 1A, and the differences therebetween are described as follows.

The semiconductor package 1B may further include optical connectors 10c1, electrical connectors 10c2, a memory device 600', a SiPh structure 700', an interconnect structure 700R', and a molding layer 800.

The optical connectors 10c1 may be optically coupled to the optical interposer 20. In some embodiments, the optical connectors 10c1 are optically coupled to the optical terminals 220 and the optical waveguide 210. In some embodiments, the optical connectors 10c1 include silicon, silicon oxynitride, silicon nitride, a polymer waveguide including cladding polymer and core polymer, or other suitable material.

The electrical connectors 10c2 may be electrically connected to electrically conductive features (not shown in FIG. 1B) of the optical interposer 20. In some embodiments, the electrical connectors 10c2 include metal pillars and solder regions, which may be used for solder bonding. In some embodiments, the electrical connectors 10c2 include solder balls.

The memory device 600′ may be disposed over and optically coupled to the optical interposer 20. In some embodiments, similar to the memory device 600, the memory device 600′ includes a logic die and a memory component including a device region. The memory device 600′ is similar to the memory device 600, the SiPh structure 700′ is similar to the SiPh structure 700, the interconnect structure 700R′ is similar to the interconnect structure 700R, and the detailed description thereof is omitted hereinafter. The SiPh structure 700′ may be formed on or bonded to a back surface of the memory device 600′ and electrically connected to the device region of the logic die of the memory device 600′. In some embodiments, the memory device 600′ is configured to communicate with the device region 100D of the substrate 100 through an optical coupling between the SiPh structure 200 and the SiPh structure 700′.

The molding layer 800 may surround or cover the substrate 100, the optical connectors 10c1, the electrical connectors 10c2, the memory devices 600 and 600', and the SiPh structures 700 and 700′. In some embodiments, the molding layer 800 includes a polymer material or another suitable insulating material.

FIG. 1C is a perspective view of a portion of a semiconductor package according to one or more embodiments of the present disclosure. In some embodiments, FIG. 1C shows an element 800t (e.g., an electronic element, an electronic device, or an electronic component) of an EIC that is integrated into an interconnect structure of a semiconductor package according to one or more embodiments of the present disclosure. In some embodiments, the element 200t of the semiconductor package 1A, the element 700t of the semiconductor package 1A, the element 200t of the semiconductor package 1B, and/or the element 700t of the semiconductor package 1B may include a structure the same as or similar to that of the element 800t.

The element 800t may be referred to as a vertical transistor element. In some embodiments, the element 800t includes a plurality of transistor units 81 arranged separately along a direction D1. The transistor units 81 may be separated from each other by a separation structure 82. The number of the transistor units 81 in one element 800t can be adjusted according to required design. In some embodiments, one element 800t may include about 10 to about 200 transistor units 81.

In some embodiments, the transistor unit 81 of the element 800t includes a central portion, a channel layer 814, a gate dielectric layer 815 and a gate electrode layer 816. The central portion includes a central isolation structure 811 and conductive regions 812 and 813.

The central isolation structure 811 may include dielectric materials or isolation materials, such as oxide-based materials. The conductive regions 812 and 813 may be disposed beside opposite sides of the central isolation structure 811, so that the central isolation structure 811 is sandwiched by the conductive regions 812 and 813 along the direction D1. The conductive regions 812 and 813 may be referred to as source/drain regions. Source/drain region(s) may refer to a source or a drain, individually or collectively dependent upon the context. In some embodiments, the conductive regions 812 and 813 may include tungsten (W), copper (Cu), titanium nitride (TiN), tantalum nitride (TaN), aluminum (Al), ruthenium (Ru), cobalt (Co), indium tin oxide (ITO), doped semiconductor material (e.g., p-doped or n-doped silicon), and/or other metals. In some embodiments, the conductive region 812 is electrically connected to a conductive pattern of an interconnect layer 83 of a BEOL interconnect structure (e.g., the interconnect structure 200R and/or 700R), and the conductive region 813 is electrically connected to another conductive pattern of the interconnect layer 83. The interconnect layer 83 may be referred to as the electrical portion 200e, the interconnect layer 200c, the electrical portion 700e, and/or the interconnect layer 700c. The separation structure 82 may be referred to as the dielectric structure 200d and/or the dielectric structure 700d.

The channel layer 814 may surround the central portion and thus serves as a sidewall of the central portion. In some embodiments, the channel layer 814 extends in a direction D2 that is substantially perpendicular to the direction D1. The channel layer 814 may be an N-type channel or a P-type channel. When the channel layer 814 is an N-type channel, the channel layer 814 may include indium gallium zinc oxide (IGZO), ZnO, In₂O₃, SnO₂, and so on. When the channel layer 814 is a P-type channel, the channel layer 814 may include NiO, Cu₂O, CuAlO₂, CuGaO₂, CuInO₂, SrCu₂O₂, SnO, and so on. The channel 814 may have a ring shape from a top view perspective. The ring-shaped channel 814 may abut sidewalls of the conductive regions 812 and 813. The channel layer 814 in the vertical transistor element 800t may be disposed in a BEOL interconnect structure (e.g., the interconnect structure 200R and/or 700R).

The gate dielectric layer 815 may surround the channel layer 814 so that the channel layer 814 is sandwiched by the gate dielectric layer 815 and the central portion of the element 800t. The gate dielectric layer 815 may extend in the direction D2. The gate dielectric layer 815 may be formed of a high-k dielectric material. The gate electrode layer 816 may surround the gate dielectric layer 815 so that the gate dielectric layer 815 is sandwiched by the gate electrode layer 816 and the channel layer 814. The gate electrode layer 816 may include a metallic material, polycrystalline silicon, doped silicon, or a metal compound, such as metal nitride. In some embodiments, the gate electrode layer 816 is electrically connected to another interconnect layer 83 of the BEOL interconnect structure (e.g., the interconnect structure 200R and/or 700R).

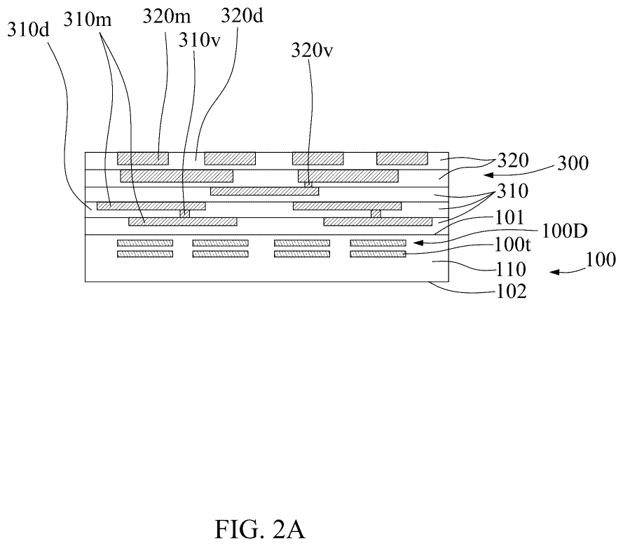

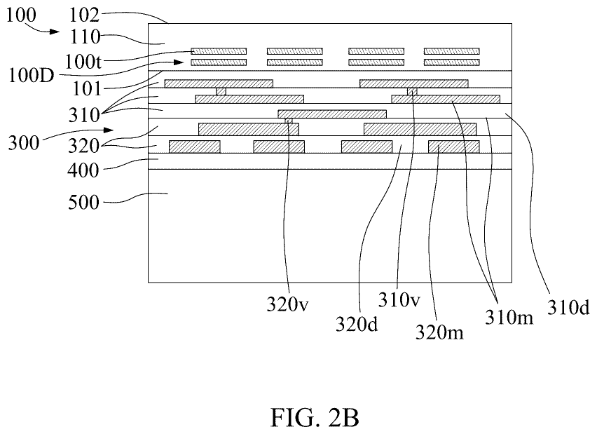

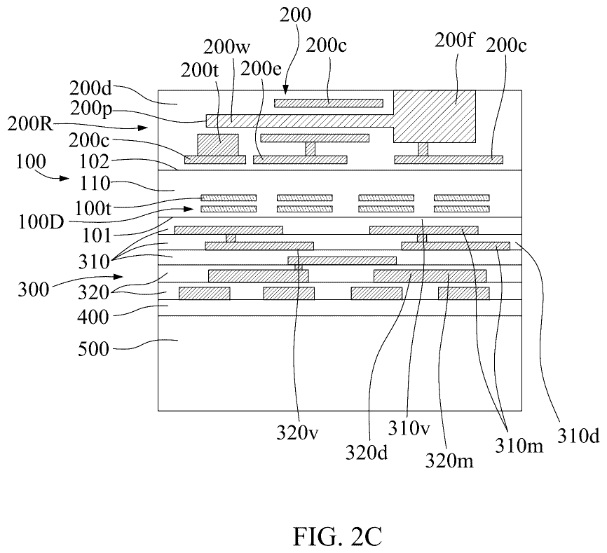

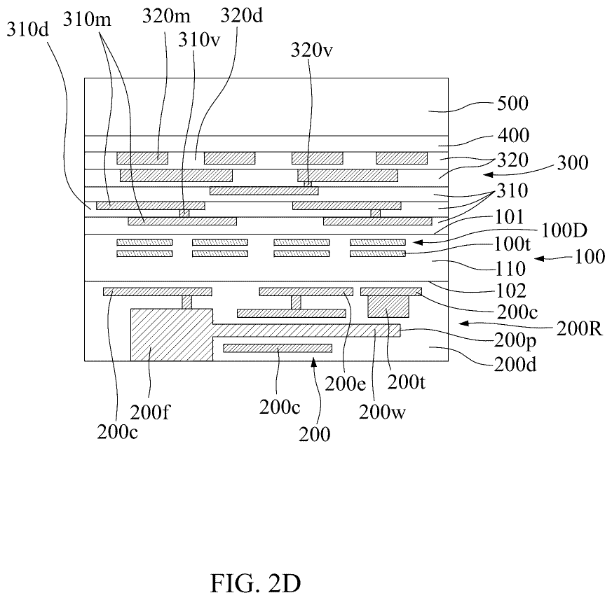

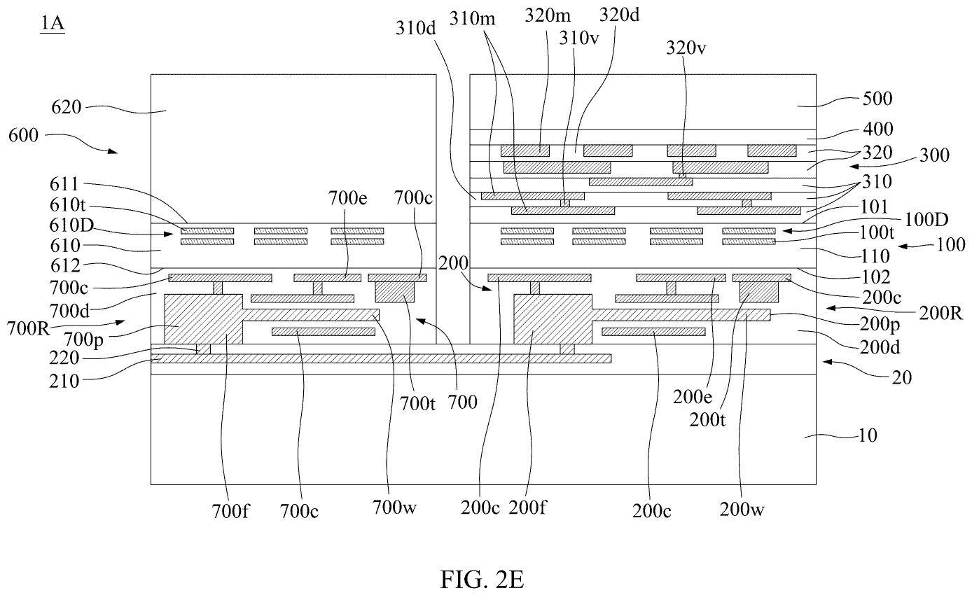

FIGS. 2A to 2E are cross-sections illustrating a method for forming a semiconductor package 1A according to one or more embodiments of the present disclosure.

Referring to FIG. 2A, a substrate 100 including a device region 100D may be provided, and an interconnect structure 300 including interconnect layers 310 and 320 may be formed over the device region 100D of the substrate 100. In some embodiments, a semiconductor layer 110 is provided, and device layers 100t including a plurality of transistors are formed adjacent to a front surface 101 to form the device region 100D at the front surface 101 of the substrate 100. In some embodiments, dielectric layers 310d and 320d are formed on the front surface 101 of the substrate 100, and metal lines 310m, 310v, 320m, and 320v are formed in the dielectric layers 310d and 320d to form the interconnect layers 310 and 320.

Referring to FIG. 2B, the structure as shown in FIG. 2A may be flipped over with a back surface 102 facing upwards and bonded to a carrier wafer 500 through a bonding layer 400.

Referring to FIG. 2C, one or more circuit layers (e.g., one or more electrical portions 200e and/or one or more interconnect layers 200c) may be formed on the back surface 102 of the substrate 100, one or more photonic devices (e.g., one or more optical portions 200p) may be formed on the one or more circuit layers, and another one or more circuit layers (e.g., another one or more electrical portions 200e and/or one or more interconnect layers 200c) may be formed on the photonic device. In some embodiments, the electrical portions 200e may form interconnect layers and at least one element 200t of an EIC, and the optical portions 200p may form elements 200w and 200f of a PIC. In some embodiments, the elements 200w and 200f are formed after forming the element 200t. In some embodiments, a processing temperature of the elements 200w and 200f is lower than a processing temperature of the element 200t. In some embodiments, a processing temperature of the elements 200w and 200f is lower than a processing temperature of the element 200t. In some embodiments, a dielectric structure 200d may be formed by forming a plurality of dielectric layers to contact the back surface 102 and cover the electrical portions 200e (e.g., the element 200t), the interconnect layers 200c, and the optical portions 200p (e.g., the elements 200w and 200f) so as to form a SiPh structure 200 including a PIC connected to the back surface 102 of the substrate 100 and to from an interconnect structure 200R including the interconnect layers 200c.

Referring to FIG. 2D, the structure shown in FIG. 2C may be flipped over, and the carrier wafer 500 may be thinned. In some embodiments, the carrier wafer 500 is thinned by a grinding process.

Referring to FIG. 2E, an optical interposer 20 including an optical waveguide 210 and optical terminals 220 may be provided, and the substrate 100 may be connected to the optical interposer 20 through the SiPh structure 200. In some embodiments, an interconnect structure 700R integrated with a SiPh structure 700 is connected to a memory device 600 including a logic die 610 and a memory component 620, and then the memory device 600 is connected to the optical interposer 20 through the SiPh structure 700. In some embodiments, the memory component 620 is connected to a front surface 611 of the logic die 610, and the SiPh structure 700 is formed on a back surface 612 of the logic die 610. As such, the semiconductor package 1A may be formed.

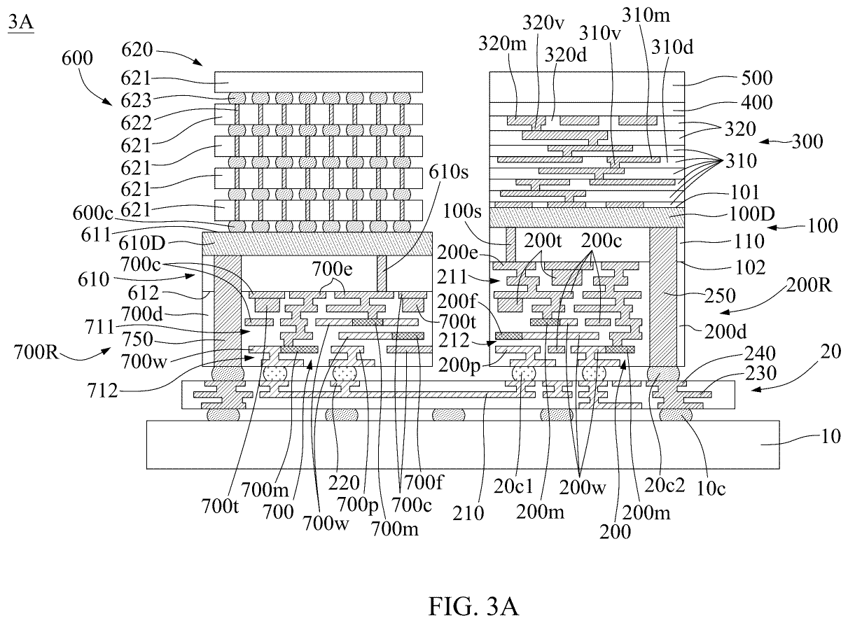

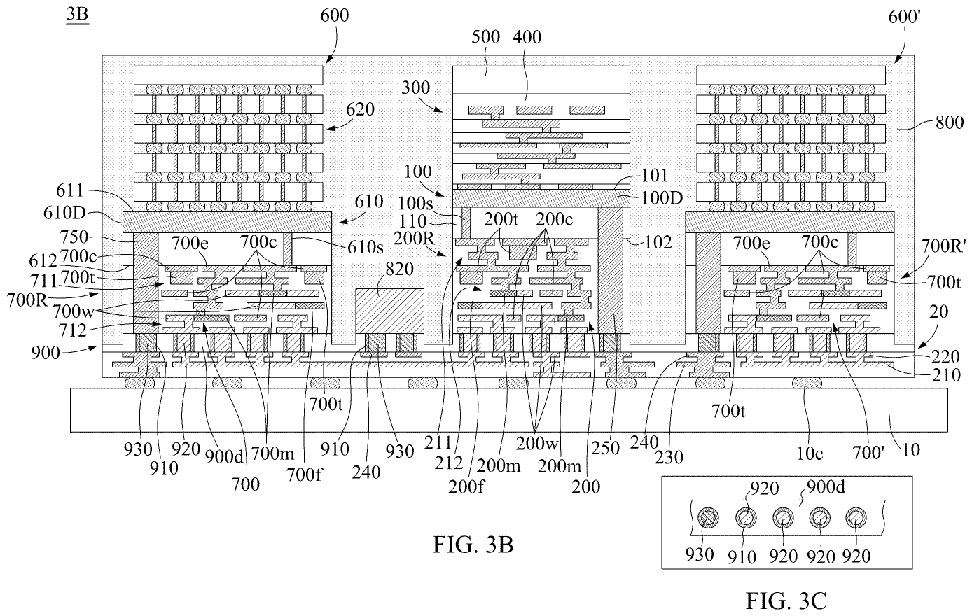

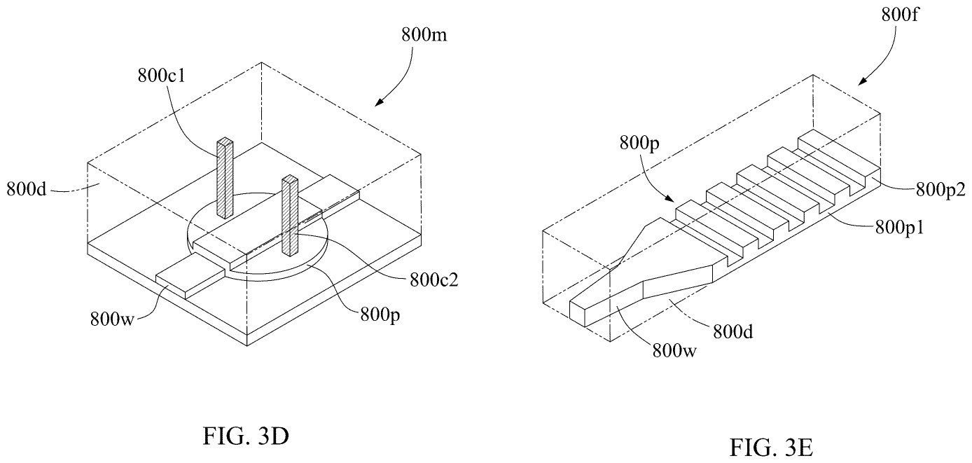

FIG. 3A is a cross-sectional view of a semiconductor package 3A according to one or more embodiments of the present disclosure. The semiconductor package 3A illustrated in FIG. 3A is similar to the semiconductor package 1A illustrated in FIG. 1A, and the differences therebetween are described as follows.

In some embodiments, the optical interposer 20 is disposed below the substrate 100 and optically coupled to the substrate 100 through the PIC 212. In some embodiments, the optical interposer 20 includes one or more optical coupling elements, such as optical waveguides 210 and optical terminals 220. In some embodiments, the optical interposer 20 further includes one or more electrical coupling elements, such as electrically conductive layers 230 and electrically conductive terminals 240. The optical coupling elements may include silicon, silicon oxynitride, silicon nitride, a polymer waveguide including cladding polymer and core polymer, or other suitable material. The electrical coupling elements may include conductive features, such as copper or another suitable conductive material. The optical waveguide 210 and the optical terminals 220 collectively may be referred to as an optical coupling structure configured to communicate with the device region 100D in the substrate 100 through the SiPh structure 200. The electrically conductive layers 230 and the electrically conductive terminals 240 collectively may be referred to as an electrical conductive structure configured to provide power to the power via 250.

In some embodiments, the SiPh structure 200 includes an EIC 211 and a PIC 212, and the semiconductor package 3A further includes a power via 250 penetrating the dielectric structure 200d. In some embodiments, the EIC 211 includes the electrical portions 200e between the substrate 100 and the PIC 212. In some embodiments, the PIC 212 is electrically connected to and integrated with the EIC 211. In some embodiments, the EIC 211 is between the PIC 212 and the substrate 100 (or the logic device) and integrated into the interconnect structure 200R. In some embodiments, the PIC 212 and the EIC 211 are integrated into the interconnect structure 200R (or the routing structure). In some embodiments, the dielectric structure 200d covers the EIC 211 and the PIC 212 and contacts the back surface 102 of the substrate 100. In some embodiments, the logic die (or the logic circuit), the EIC 211, and the PIC 212 share the semiconductor layer 110 of the substrate 100. In some embodiments, the EIC 211 includes the electrical portions 200e between the device region 100D and the PIC 212. In some embodiments, the EIC 211 includes at least an element 200t having a structure the same as or similar to that of the element 800t illustrated in FIG. 1C. In some embodiments, the PIC 212 includes elements 200w, 200f, and 200m. In some embodiments, the element 200w is a waveguide optically coupled to the element 200f, the element 200m, and/or the optical terminal 220 of the optical interposer 20. In some embodiments, the element 200m includes a photodetector and/or a modulator that is electrically connected to the EIC 211 and optically coupled to the waveguide. In some embodiments, the element 200f includes a laser configured to provide optical signals to the PIC 212 and/or a coupler that is optically coupled to the waveguide, the photodetector, and/or the modulator.

In some embodiments, the power via 250 passes through the dielectric structure 200d and the substrate 100 (e.g., the semiconductor layer 110) to connect to the device region 100D. In some embodiments, the power via 250 is configured to provide power supplied from the carrier 10 through the electrically conductive layers 230 and the conductive terminals 240 to the device region 100D of the substrate 100. In some embodiments, the SiPh structure 200 is electrically connected to the device region 100D through a conductive via 100s (or a through silicon via (TSV)) disposed in the substrate 100. In some embodiments, the conductive via 100s is disposed or formed within the semiconductor layer 110 of the substrate 100. In some embodiments, the conductive via 100s electrically connects the EIC 211 to the device region 100D of the substrate 100.

In some embodiments, the memory component 620 includes a memory stacking including memory dies 621. In some embodiments, the memory component 620 further includes vias 622 passing through the memory dies 621 and conductive features 623 to electrically connect the memory dies 621 to one another. In some arrangements, the memory component 620 is electrically connected to the device region 610D of the logic die 610 through electrical connectors 600c.

In some embodiments, the SiPh structure 700 includes an EIC 711, a PIC 712, and a power via 750 penetrating the dielectric structure 700d. In some embodiments, the PIC 712 is electrically connected to and integrated with the EIC 711. In some embodiments, the PIC 712 and the EIC 711 are integrated into the interconnect structure 700R (or the routing structure). In some embodiments, the logic circuit in the device region 610D, the EIC 711, and the PIC 712 share the semiconductor layer of the logic die 610. In some embodiments, the EIC 711 includes the electrical portions 700e between the logic die 610 and the PIC 712. In some embodiments, the EIC 711 includes at least an element 700t having a structure the same as or similar to that of the element 800t illustrated in FIG. 1C. In some embodiments, the PIC 712 includes elements 700w, 700f, and 700m. In some embodiments, the element 700w is a waveguide optically coupled to the element 700f, the element 700m, and/or the optical terminal 220 of the optical interposer 20. In some embodiments, the element 700m includes a photodetector and/or a modulator that is electrically connected to the EIC 711 and optically coupled to the waveguide. In some embodiments, the element 700f includes a laser configured to provide optical signals to the PIC 712 and/or a coupler that is optically coupled to the waveguide, the photodetector, and/or the modulator.

In some embodiments, the power via 750 passes through the dielectric structure 700d and the logic die 610 (e.g., the semiconductor layer of the logic die 610) to connect to the device region 610D. In some embodiments, the power via 750 is configured to provide power supplied from the carrier 10 through the electrically conductive layers 230 and the conductive terminals 240 to the memory device 600. In some embodiments, the SiPh structure 700 is electrically connected to the memory device 600 through a conductive via 610s (or a through silicon via (TSV)) disposed in the logic die 610. In some embodiments, the conductive via 610s is disposed or formed within the semiconductor layer of the logic die 610.

In some embodiments, the semiconductor package 3A further includes optical connectors 20c1 and electrical connectors 20c2. In some embodiments, the optical connectors 20c1 optically couple the PICs 212 and 712 to the optical interposer 20. In some embodiments, the electrical connectors 20c2 electrically connect the power vias 250 and 750 to the carrier 10 through the electrically conductive layers 230 and the conductive terminals 240.

FIG. 3B is a cross-sectional view of a semiconductor package 3B according to one or more embodiments of the present disclosure. FIG. 3C is a top view of a portion of a semiconductor package 3B according to one or more embodiments of the present disclosure. The semiconductor package 3B illustrated in FIG. 3B is similar to the semiconductor package 3A illustrated in FIG. 3A, and the differences therebetween are described as follows.

The semiconductor package 3B may further include a memory device 600′, a SiPh structure 700′, an interconnect structure 700R′, a molding layer 800, an optical device 820, and a hybrid-bond structure 900.

In some embodiments, the SiPh structures 200, 700, and 700′ are connected to or bonded to the optical interposer 20 through the hybrid-bond structure 900. In some embodiments, the optical interposer 20 optically couples to the PICs 212 and 712 through the hybrid-bond structure 900. In some embodiments, the PIC 212 is vertically stacked between the optical interposer 20 and the substrate 100 (or the logic device. In some embodiments, the PIC 712 is vertically stacked between the optical interposer 20 and the substrate 100 (or the logic device. In some embodiments, the EIC 211 includes the electrical portions 200e between the device region 100D and the PIC 212. In some embodiments, the EIC 211 includes at least an element 200t having a structure the same as or similar to that of the element 800t illustrated in FIG. 1C. In some embodiments, the PIC 212 includes elements 200w, 200f, and 200m. In some embodiments, the EIC 711 includes at least an element 700t having a structure the same as or similar to that of the element 800t illustrated in FIG. 1C. In some embodiments, the PIC 712 includes elements 700w, 700f, and 700m.

In some embodiments, the hybrid-bond structure 900 includes a dielectric layer 900d, conductive layers 910, optical channels 920, and electrical channels 930. In some embodiments, the optical channels 920 optically couple the PICs 212 and 712 to the optical interposer 20. In some embodiments, the electrical channels 930 electrically connect the power vias 250 and 750 to the carrier 10 through the electrically conductive layers 230 and the conductive terminals 240.

In some embodiments, the conductive layers 910 include electrically conductive materials. In some embodiments, the conductive layers 910 include metal, such as copper or other suitable metal material, and at least the dielectric layer 900d and the conductive layers 910 collectively construct the hybrid-bond structure 900. In some embodiments, the optical channels 920 include dielectric materials, such as silicon nitride or other suitable material, the electrical channels 930 include electrically conductive materials, such as copper or other suitable material. In some embodiments, the dielectric layer 900d, the conductive layers 910, the optical channels 920, and the electrical channels 930 collectively construct the hybrid-bond structure 900.

Referring to FIG. 3C, which shows a top view of a portion of the hybrid-bond structure 900, in some embodiments, each of the optical channels 920 and the electrical channels 930 is surrounded by one of the conductive layers 910. The conductive layer 910 may include a metal ring, such as a Cu ring.

In some embodiments, the optical device 820 includes a laser device (e.g., a laser die) configured to provide one or more optical signals to the SiPh structures 200 and 700. In some embodiments, the optical device 820 is electrically connected to the conductive terminals 240 through the hybrid-bond structure 900.

In some embodiments, signal communication between the logic circuits (e.g., the device region 100D of the substrate 100) and external components (e.g., the memory device 600 or the memory component 620) are achieved by optical communication through the optical interposer 20. In some embodiments, the optical interposer 20 includes optical channels (e.g., the optical waveguide 210 and the optical terminals 220) for communication between the logic circuits and other components. The optical interposer 20 further includes an electrically conductive structure (e.g., electrically conductive layers 230, electrically conductive terminals 240, and electrically conductive vias connected therebetween) for power supply. In some embodiments, a semiconductor device including the EIC 211 and the PIC 212 integrated into the back side routing structure on the back surface 102 of the substrate 100 is hybrid-bonded to the optical interposer 20. In some embodiments, the memory devices 600 and 600′ including the logic dies 610 are further integrated with EICs 711 and PICs 712 and hybrid-bonded to the optical interposer 20.

FIG. 3D is a perspective view of a portion of a semiconductor package according to one or more embodiments of the present disclosure. In some embodiments, FIG. 3D shows an element 800m (e.g., an optical element, a photonic device, or a photonic component) of a PIC that is integrated into an interconnect structure of a semiconductor package according to one or more embodiments of the present disclosure. In some embodiments, the element 200m of the semiconductor package 1A, the element 700m of the semiconductor package 1A, the element 200m of the semiconductor package 1B, the element 700m of the semiconductor package 1B, the element 200m of the semiconductor package 3A, the element 700m of the semiconductor package 3A, the element 200m of the semiconductor package 3B, and/or the element 700m of the semiconductor package 3B may include a structure the same as or similar to that of the element 800m. The element 800m may be or include an optical modulator.

In some embodiments, the element 800m includes an optical coupling layer 800p, an optical waveguide 800w, and electrically conductive vias 800c1 and 800c2. In some embodiments, the element 800m is within or covered by a dielectric structure 800d. In some embodiments, the optical coupling layer 800p is disposed or formed crossing the optical waveguide 800w. The optical coupling layer 800p may include VO₂, In₂O₃, BaTiO₃, ITO, or the like. In some embodiments, the electrically conductive vias 800c1 and 800c2 are connected to two portions of the optical coupling layer 800p at opposite sides of the optical waveguide 800w. The element 800m may convert an optical signal received from one end of the optical waveguide 800w to a modulated optical signal according to the electrical signal received from the electrically conductive vias 800c1 and 800c2 and then send out the modulated optical signal through another end of the optical waveguide 800w.

The optical coupling layer 800p may be referred to as the optical portion 200p and/or the optical portion 700p. The optical waveguide 800w may be referred to as the element 200f and/or the element 700f. The electrically conductive vias 800c1 and 800c2 may be referred to as the electrical portion 200e, the interconnect layer 200c, the electrical portion 700e, and/or the interconnect layer 700c. The dielectric structure 800d may be referred to as the dielectric structure 200d and/or the dielectric structure 700d.

FIG. 3E is a perspective view of a portion of a semiconductor package according to one or more embodiments of the present disclosure. In some embodiments, FIG. 3E shows a element 800f (e.g., an optical element, a photonic device, or a photonic component) of a PIC that is integrated into an interconnect structure of a semiconductor package according to one or more embodiments of the present disclosure. In some embodiments, the element 200f of the semiconductor package 1A, the element 700f of the semiconductor package 1A, the element 200f of the semiconductor package 1B, the element 700f of the semiconductor package 1B, the element 200f of the semiconductor package 3A, the element 700f of the semiconductor package 3A, the element 200f of the semiconductor package 3B, and/or the element 700f of the semiconductor package 3B may include a structure similar to that of the element 800f. The element 800f may be or include an optical coupler, e.g., a grating coupler.

In some embodiments, the element 800f includes an optical coupling layer 800p and an optical waveguide 800w. In some embodiments, the element 800f is within or covered by a dielectric structure 800d. In some embodiments, the optical coupling layer 800p is connected and optically coupled to the optical waveguide 800w. In some embodiments, the optical coupling layer 800p includes a base layer 800p1 and a plurality of optical strips 800p2 formed on and connected to the base layer 800p1. The optical strips 800p2 may have predetermined widths and spaced part from one another by predetermined gaps so as to allow the optical signal transmitted from the optical waveguide 800w to optically couple to another optical waveguide that is disposed above the element 800f.

The optical coupling layer 800p may be referred to as the optical portion 200p and/or the optical portion 700p. The optical waveguide 800w may be referred to as the element 200f and/or the element 700f. The dielectric structure 800d may be referred to as the dielectric structure 200d and/or the dielectric structure 700d.

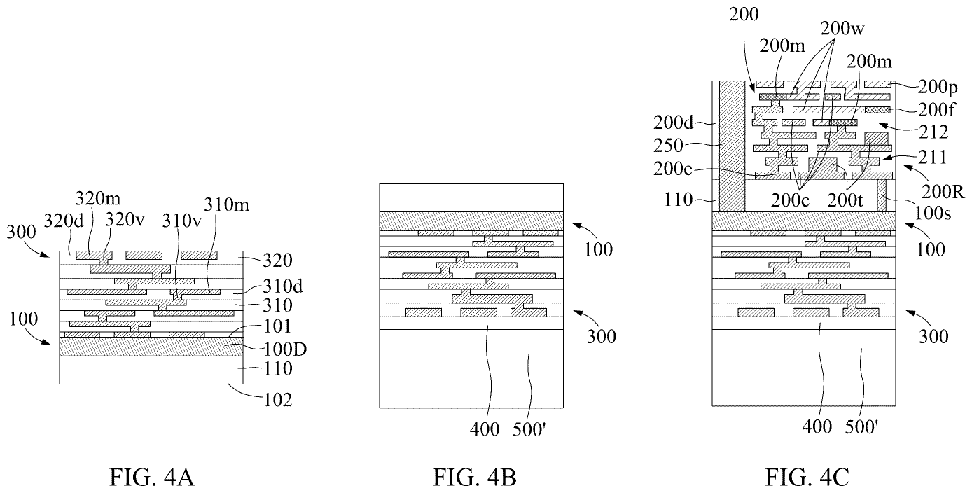

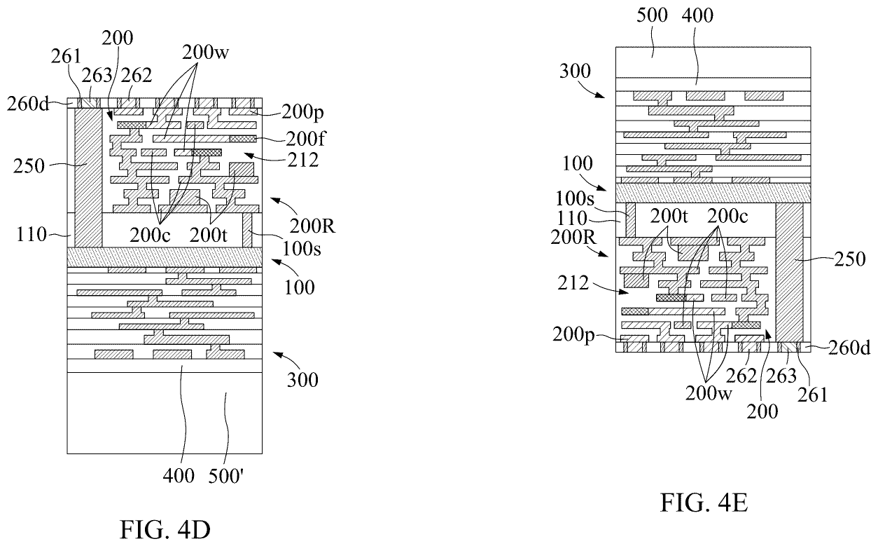

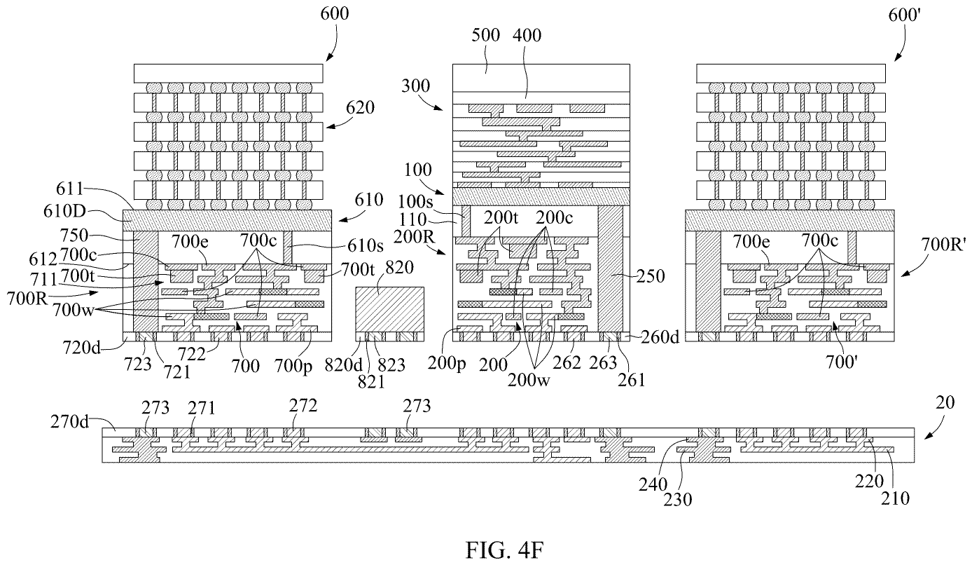

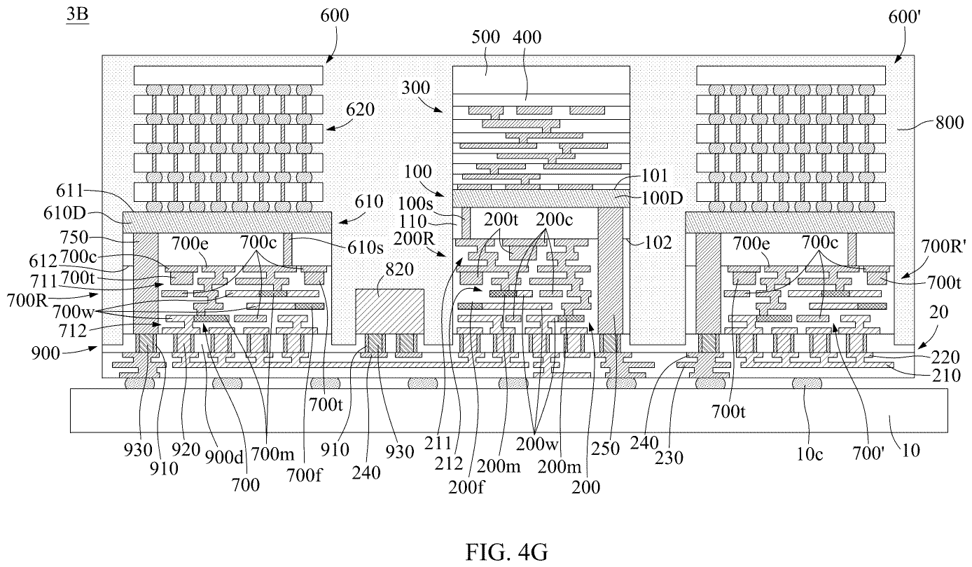

FIGS. 4A to 4G are cross-sections illustrating a method for forming a semiconductor package 3B according to one or more embodiments of the present disclosure.

Referring to FIG. 4A, a substrate 100 including a device region 100D may be provided, and an interconnect structure 300 including interconnect layers 310 and 320 may be formed over the device region 100D of the substrate 100. In some embodiments, a semiconductor layer 110is provided, and device layers 100t including a plurality of transistors are formed adjacent to a front surface 101 to form the device region 100D at the front surface 101 of the substrate 100. In some embodiments, dielectric layers 310d and 320d are formed on the front surface 101 of the substrate 100, and metal lines 310m, 310v, 320m and 320v are formed in the dielectric layers 310d and 320d to form the interconnect layers 310 and 320.

Referring to FIG. 4B, the structure as shown in FIG. 4A may be flipped over with a back surface 102 facing upwards and bonded to a carrier wafer 500′ through a bonding layer 400.

Referring to FIG. 4C, vias may be formed within the semiconductor layer of the substrate 100, and conductive materials may be formed in the vias to form a conductive via 100s (or a TSV) and a lower portion of a power via 250 within the semiconductor layer 110 of the substrate 100. Next, one or more circuit layers (e.g., one or more electrical portions 200e and/or one or more interconnect layers 200c) may be formed on the back surface 102 of the substrate 100, one or more photonic devices (e.g., one or more optical portions 200p) may be formed on the one or more circuit layers, and another one or more circuit layers (e.g., another one or more electrical portions 200e and/or one or more interconnect layers 200c) may be formed on the photonic device. In some embodiments, the electrical portions 200e may form interconnect layers and elements 200t of an EIC 211, and the optical portions 200p may form elements 200w, 200m, and 200f of a PIC 212. In some embodiments, the elements 200w, 200m, and 200f are formed after forming the elements 200t. In some embodiments, a processing temperature of the elements 200w, 200m, and 200f is lower than a processing temperature of the elements 200t. In some embodiments, a dielectric structure 200d may be formed by forming a plurality of dielectric layers to contact the back surface 102 and cover the electrical portions 200e (e.g., the elements 200t), the interconnect layers 200c, and the optical portions 200p (e.g., the elements 200w, 200m, and 200f) so as to form a SiPh structure 200 including the PIC 212 connected to the back surface 102 of the substrate 100 and to from an interconnect structure 200R including the interconnect layers 200c. In some embodiments, a via may be formed within the dielectric structure 200d, and a conductive material may be formed in the via to form an upper portion of the power via 250, so as to form the power via 250 passing through the dielectric structure 200d to connect to the device region 100D.

Referring to FIG. 4D, a dielectric layer 260d may be formed on exposed surfaces of the power via 250, the optical portions 200p, and the dielectric structure 200d, and vias may be formed within the dielectric layer 260d to expose the power via 250 and the optical portions 200p. In some embodiments, a metal material may be formed in the vias to form metal layers 261 on sidewalls of the vias. In some embodiments, a conductive material may be formed in the via of the dielectric layer 260d that exposes the power via 250 to form a bonding pad 263 surrounded by the metal layer 261. In some embodiments, optical coupling materials (e.g., silicon, silicon oxynitride, silicon nitride, a polymer waveguide material, or other suitable material) may be formed in the vias of the dielectric layer 260d that expose the optical portions 200p to form optical channels 262. In some embodiments, the materials of the optical channels 262 may be dielectric materials. In some embodiments, a planarization process may be performed to form a planarized bonding surface including the surfaces of the dielectric layer 260d, the metal layers 261, the optical channels 262, and the bonding pad 263.

Referring to FIG. 4E, the structure shown in FIG. 4D may be flipped over, and the carrier wafer 500′ may be thinned to form a carrier wafer 500. In some embodiments, the carrier wafer 500′ is thinned by a grinding process.

Referring to FIG. 4F, an optical interposer 20 including an optical waveguide 210, optical terminals 220, electrically conductive layers 230, and electrically conductive terminals 240 may be provided, and the substrate 100 may be connected to the optical interposer 20 through the SiPh structure 200. In some embodiments, an interconnect structure 700R integrated with a SiPh structure 700 including an EIC 711 and a PIC 712 is connected to a memory device 600 including a logic die 610 and a memory component 620, and then the memory device 600 is connected to the optical interposer 20 through the SiPh structure 700. In some embodiments, the memory component 620 is connected to a front surface 611 of the logic die 610, and the SiPh structure 700 is formed on a back surface 612 of the logic die 610. In some embodiments, the PIC 712 is formed on the back surface 612 of the logic die 610, and the memory device 600 is connected to the optical interposer 20 through the PIC 712.

Still referring to FIG. 4F, a dielectric layer 720d may be formed on exposed surfaces of the power via 750, the optical portions 700p, and the dielectric structure 700d, and vias may be formed within the dielectric layer 720d to expose the power via 750 and the optical portions 700p. In some embodiments, a metal material may be formed in the vias to form metal layers 721 on sidewalls of the vias. In some embodiments, a conductive material may be formed in the via of the dielectric layer 720d that exposes the power via 750 to form a bonding pad 723 surrounded by the metal layer 721. In some embodiments, optical coupling materials (e.g., silicon, silicon oxynitride, silicon nitride, a polymer waveguide material, or other suitable material) may be formed in the vias of the dielectric layer 720d that expose the optical portions 700p to form optical channels 722. In some embodiments, the materials of the optical channels 722 may be dielectric materials. In some embodiments, a planarization process may be performed to form a planarized bonding surface including the surfaces of the dielectric layer 720d, the metal layers 721, the optical channels 722, and the bonding pad 723.

Still referring to FIG. 4F, a dielectric layer 270d may be formed on a surface of the optical interposer 20, and vias may be formed within the dielectric layer 270d to expose the optical terminals 220 and the electrically conductive terminals 240. In some embodiments, a metal material may be formed in the vias to form metal layers 271 on sidewalls of the vias. In some embodiments, a conductive material may be formed in the vias of the dielectric layer 270d that expose the electrically conductive terminals 240 to form bonding pads 273 surrounded by the metal layer 271. In some embodiments, optical coupling materials (e.g., silicon, silicon oxynitride, silicon nitride, a polymer waveguide material, or other suitable material) may be formed in the vias of the dielectric layer 270d that expose the optical terminals 220 to form optical channels 272. In some embodiments, the materials of the optical channels 272 may be dielectric materials. In some embodiments, a planarization process may be performed to form a planarized bonding surface including the surfaces of the dielectric layer 270d, the metal layers 271, the optical channels 272, and the bonding pad 273.

Still referring to FIG. 4F, similar to the formation of the planarized bonding surface including the surfaces of the dielectric layer 270d, the metal layers 271, the optical channels 272, and the bonding pad 273, a planarized bonding surface including surfaces of a dielectric layer 820d, metal layers 821 within the dielectric layer 820d, and bonding pads 823 surrounded by the metal layers 821 may be formed on a surface of the a optical device 820. Next, the SiPh structures 200, 700, and 700′ and the optical device 820 may be connected to the optical interposer 20 by bonding the planarized bonding surfaces by hybrid bonding technique.

Referring to FIG. 4G, a hybrid bonding process may be performed to bond the metal layers 261, 721, and 821 to the metal layers 271 to form conductive layers 910, to bond the bonding pads 263, 723, and 823 to the bonding pads 273, and to bond the dielectric layers 260d, 720d, and 820d to the dielectric layer 270d to form a dielectric layer 900d, so as to form a hybrid-bond structure 900 that connects the SiPh structures 200, 700, and 700′ and the optical device 820 to the optical interposer 20. In some embodiments, the optical channels 262 and 722 include dielectric materials and thus are connected to the optical channels 720 also including dielectric materials by hybrid bonding to form the optical channels 920 that are included in the hybrid-bond structure 900. A molding layer 800 may be formed to surround or cover the substrate 100, the memory devices 600 and 600′, the SiPh structures 700 and 700', and the optical device 820. The optical interposer 20 may be connected to a carrier 10 through electrical connectors 10c. As such, the semiconductor package 3B may be formed.

Some embodiments of the present disclosure provide a semiconductor package. The semiconductor package includes a substrate, an interconnect structure, a device region, a first routing structure, and a first photonic integrated circuit (PIC). The substrate includes a device region at a front surface of the substrate, and the substrate includes a logic device. The interconnect structure is over the device region. The interconnect structure includes interconnect layers, each of the interconnect layers includes metal lines disposed in a dielectric layer, a first metal line in a first interconnect layer of the interconnect layers is spaced apart from a second metal line in a second interconnect layer of the interconnect layers by the dielectric layer. The first routing structure is disposed over a back surface of the substrate and is configured to communicate the logic device with an external component. The first PIC is integrated into the first routing structure.

Some embodiments of the present disclosure provide a semiconductor package. The semiconductor package includes a substrate, an interconnect structure, a first silicon photonic (SiPh) structure, and an optical interposer. The substrate includes a device region. The interconnect structure is disposed over the device region, wherein the interconnect structure includes interconnect layers, each of the interconnect layers includes metal lines disposed in a dielectric layer, two metal lines of the interconnect layers extend along different directions, the metal lines are spaced apart from one another by the dielectric layer, and a thickness of a respective dielectric layer in a bottommost one of the interconnect layers is less than a thickness of a respective dielectric layer in at least one of the interconnect layers above the bottommost one of the interconnect layers. The first SiPh structure is connected to a surface of the substrate and includes a first electrical integrated circuit (EIC) and a first photonic integrated circuit (PIC) integrated with the first EIC. The optical interposer is disposed below the substrate and is optically coupled to the substrate through the first PIC.

Some embodiments of the present disclosure provide a method for forming a semiconductor package. The method includes: providing a substrate including a device region at a front surface of the substrate; forming an interconnect structure over the device region, wherein the interconnect structure includes interconnect layers, each of the interconnect layers includes metal lines disposed in a dielectric layer, the metal lines are spaced apart from one another by the dielectric layer, a thickness of a respective dielectric layer in a bottommost one of the interconnect layers is less than a thickness of a respective dielectric layer in at least one of the interconnect layers above the bottommost one of the interconnect layers, a first metal line in a first interconnect layer of the interconnect layers is spaced apart from a second metal line in a second interconnect layer of the interconnect layers by the dielectric layer, and the first metal line is electrically coupled to the second metal line by a via disposed in the dielectric layer; and connecting a first photonic integrated circuit (PIC) to a back surface of the substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a substrate comprising a device region at a front surface of the substrate, the substrate comprising a logic device;
an interconnect structure over the device region, wherein the interconnect structure comprises interconnect layers, each of the interconnect layers comprises metal lines disposed in a dielectric layer, two metal lines of the interconnect layers extend along different directions, a first metal line in a first interconnect layer of the interconnect layers is spaced apart from a second metal line in a second interconnect layer of the interconnect layers by the dielectric layer, and the first metal line is electrically coupled to the second metal line by a via disposed in the dielectric layer;
a first routing structure disposed over a back surface of the substrate and configured to communicate the logic device with an external component; and
a first photonic integrated circuit (PIC) integrated into the first routing structure.

2. The semiconductor package of claim 1, further comprising a first electrical integrated circuit (EIC) between the first PIC and the logic device and integrated into the first routing structure.

3. The semiconductor package of claim 2, wherein the first routing structure further comprises a dielectric structure contacting the back surface of the substrate and covering the first PIC and the first EIC.

4. The semiconductor package of claim 1, further comprising an optical interposer optically coupled to the first PIC through a hybrid-bond structure, wherein the first PIC is vertically stacked between the optical interposer and the logic device.

5. The semiconductor package of claim 4, further comprising:
a memory device disposed over the optical interposer and comprising a logic die;
a second routing structure disposed over a back surface of the logic die; and
a second PIC integrated into the second routing structure.

6. The semiconductor package of claim 1, wherein the interconnect structure is configured to communicate logic dies at the front surface of the logic device.

7. The semiconductor package of claim 1, wherein the first PIC comprises a photodetector, a modulator, a waveguide, a coupler, or a combination thereof integrated into the first routing structure.

8. A semiconductor package, comprising:
a substrate comprising a device region;
an interconnect structure disposed over the device region, wherein the interconnect structure comprises interconnect layers, each of the interconnect layers comprises metal lines disposed in a dielectric layer, two metal lines of the interconnect layers extend along different directions, the metal lines are spaced apart from one another by the dielectric layer, and a thickness of a respective dielectric layer in a bottommost one of the interconnect layers is less than a thickness of a respective dielectric layer in at least one of the interconnect layers above the bottommost one of the interconnect layers;
a first silicon photonic (SiPh) structure connected to a surface of the substrate and comprising a first electrical integrated circuit (EIC) and a first photonic integrated circuit (PIC) integrated with the first EIC; and
an optical interposer disposed below the substrate and optically coupled to the substrate through the first PIC.

9. The semiconductor package of claim 8, further comprising a conductive via disposed in the substrate, wherein the conductive via electrically connects the first EIC to the device region of the substrate.

10. The semiconductor package of claim 9, further comprising:
a dielectric structure covering the first EIC and the first PIC; and
a power via passing through the dielectric structure and the substrate to connect to the device region.

11. The semiconductor package of claim 10, wherein the optical interposer comprises an optical coupling structure configured to communicate with the device region in the substrate through the first SiPh structure and an electrical conductive structure configured to provide power to the power via.

12. The semiconductor package of claim 8, further comprising:
a memory device disposed over the optical interposer and comprising a logic die and a memory component on a front surface of the logic die; and
a second SiPh structure connected to a back surface of the logic die, wherein the logic die is optically coupled to the optical interposer through the second SiPh structure.

13. The semiconductor package of claim 12, further comprising a hybrid-bond structure connecting the first SiPh structure and the second SiPh structure to optical terminals of the optical interposer.

14. A method for forming a semiconductor package, comprising:
providing a substrate comprising a device region at a front surface of the substrate;
forming an interconnect structure over the device region, wherein the interconnect structure comprises interconnect layers, each of the interconnect layers comprises metal lines disposed in a dielectric layer, the metal lines are spaced apart from one another by the dielectric layer, a thickness of a respective dielectric layer in a bottommost one of the interconnect layers is less than a thickness of a respective dielectric layer in at least one of the interconnect layers above the bottommost one of the interconnect layers, a first metal line in a first interconnect layer of the interconnect layers is spaced apart from a second metal line in a second interconnect layer of the interconnect layers by the dielectric layer, and the first metal line is electrically coupled to the second metal line by a via disposed in the dielectric layer; and
connecting a first photonic integrated circuit (PIC) to a back surface of the substrate.

15. The method of claim 14, wherein connecting the first PIC to the back surface of the substrate comprises:
forming a first circuit layer on the back surface of the substrate;
forming a photonic device on the first circuit layer; and
forming a second circuit layer on the photonic device.

16. The method of claim 15, wherein connecting the first PIC to the back surface of the substrate further comprises forming a dielectric structure contacting the back surface of the substrate and covering the first circuit layer, the photonic device, and the second circuit layer.

17. The method of claim 16, further comprising forming a power via passing through the dielectric structure to connect to the device region.

18. The method of claim 14, further comprising connecting the substrate to an optical interposer through the first PIC.

19. The method of claim 18, further comprising:
forming a second PIC on a back surface of a logic die of a memory device; and
connecting the memory device to the optical interposer through the second PIC.

20. The method of claim 18, wherein the first PIC is connected to the optical interposer through hybrid bonding.
